(19) United States
(12) Patent Application Publication
(10) Pub. No.: US 2006/0175042 A1
(43) Pub. Date: Aug. 10, 2006

(54) Heat dispensing device

(76) Inventor: Yung-Pin Kuo, Chang Hwa City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/052,085

(22) Filed: Feb. 8, 2005

(51) Int. Cl. H05K 7/20

(52) U.S. Cl. 165/80.3; 361/704

(57) ABSTRACT

A heat dispensing device includes a base made of copper and a plurality of aluminum fins integrally extend from the base. The fins are made by way of skving so that no agent and gap between the fins and the base. Heat can be directly transferred from the base to the fins without any impedance and the heat dispensing device is light in weight.

### FIELD OF THE INVENTION

The present invention relates to a heat dispensing device made by an integral compound material composed of copper and aluminum. The base is made by copper and the aluminum is machined by skving to be fins.

### BACKGROUND OF THE INVENTION

A conventional heat dispensing device is disclosed in FIG. 7, and generally includes a base 3 with a plurality of fins 4 attached on a top of the base 3. The base 3 is made by copper which is heavy but has high heat conductivity so that when the base 3 is put on a heat source such as a CPU, heat is quickly conducted to the copper made base 3. The aluminum fins 4 are light in weight and are attached to the base 3 by an agent such as Nickel or Tin. However, the agent between the base 3 and the fins 4 performs as an heat impedance which limits the heat being transferred from the base 3 to the fins 4 so that the efficiency of the heat dispensing device is not satisfied.

The present invention intends to provide a heat dispensing device with high efficiency and the heat dispensing device is made by compound material by copper and aluminum. The base of the dispensing device is made by copper and the fins are made by way of skving. There is no agent between the fins and the base so that heat can be transferred to the fins from the base directly and efficiently.

### SUMMARY OF THE INVENTION

The present invention relates to a heat dispensing device which comprises a base made of copper and a plurality of fins integrally extending from the base. The fins are made by aluminum and made by way of skving from the compound material of copper and aluminum.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is a perspective view to show the heat dispensing device of the present invention;

FIG. 2 shows a cross sectional view of the board made of copper and aluminum;

FIG. 3 shows the fins are made by way of skving;

FIG. 4 shows a side view of the heat dispensing device of the present invention,

FIG. 5 shows Temperature at different spots of the heat dispensing device.

FIG. 6 shows Temperature at different cutting positions for different materials, and

FIG. 7 shows a conventional heat dispensing device;

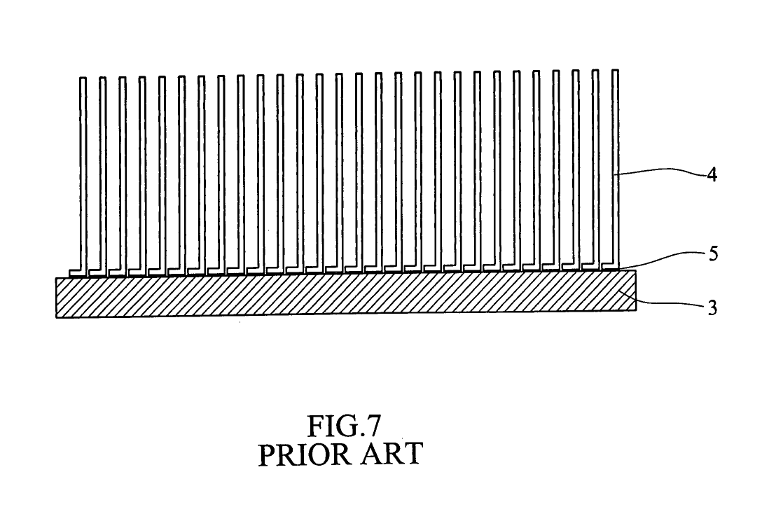

### DETAILED DESCRIPTION OF THE PREFERRED EMBODIMENT

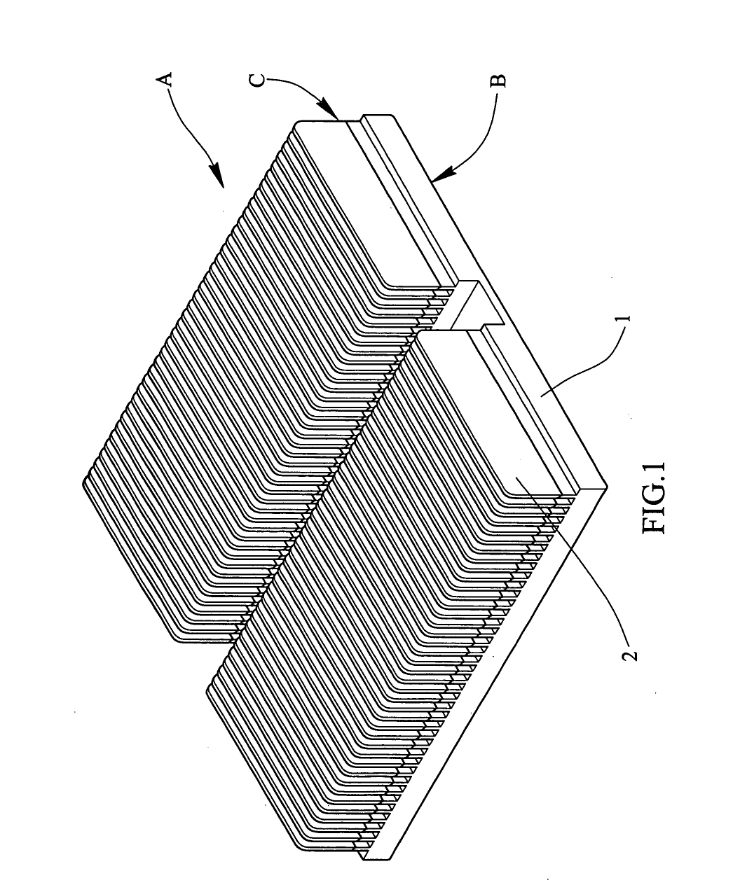

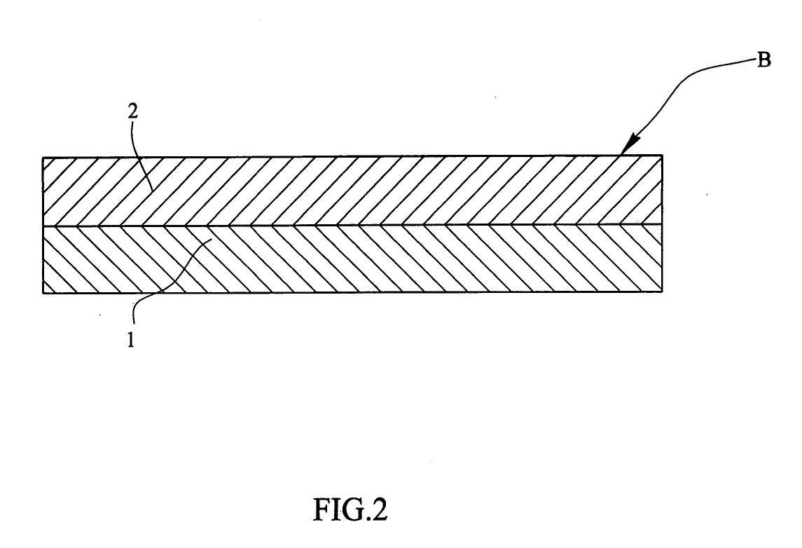

Referring to FIGS. 1 to 3, the heat dispensing device “A” of the present invention comprises a base “B” and fins group “C”.

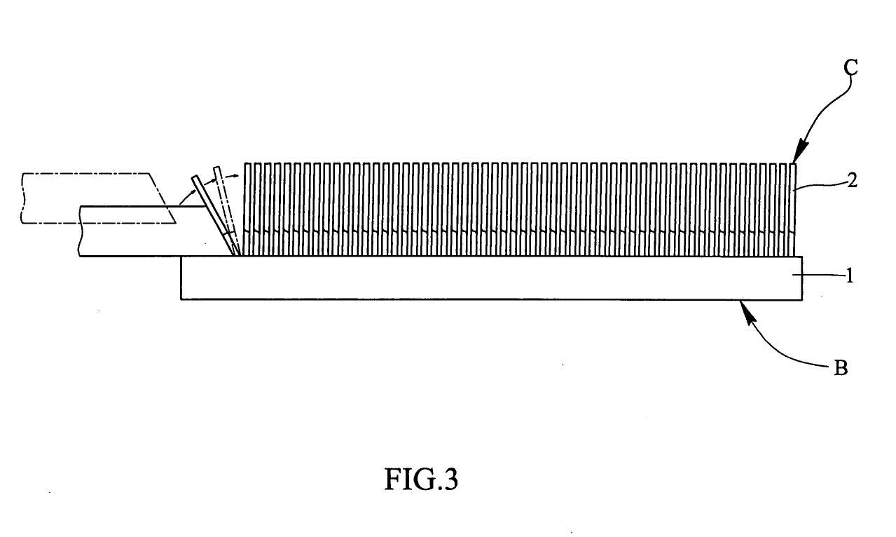

The device “A” is first made to be a block made by compound material composed of copper 1 and aluminum 2. The base “B” is made by copper 1 and the fins croup “C” is made by aluminum 2 and located at a top portion of the block. The fins group “C” is made by way of skving as shown in FIG. 3. The fins group “C” is integrally extended from the base “B” and includes a plurality of fins which are parallel with each other. There is no gap and agent between the fins and the base “B” so that heat is directly transferred to the fins without any impedance. Of course, the fins can also be made by compound material composed of copper and aluminum.

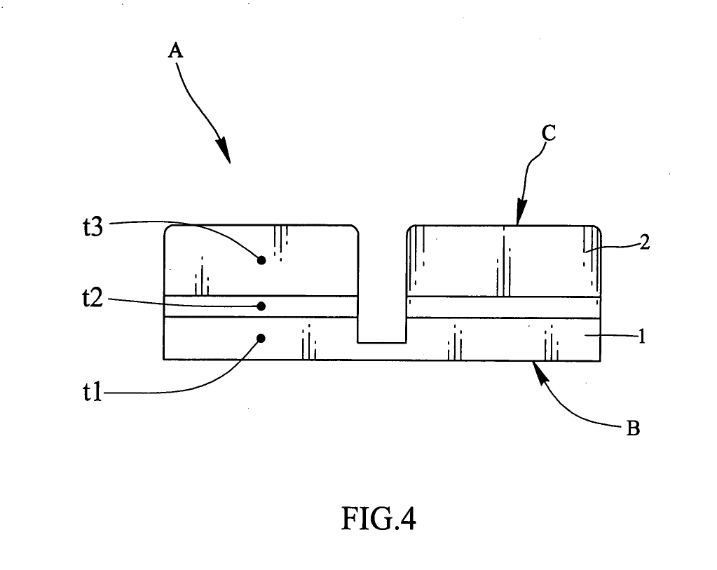

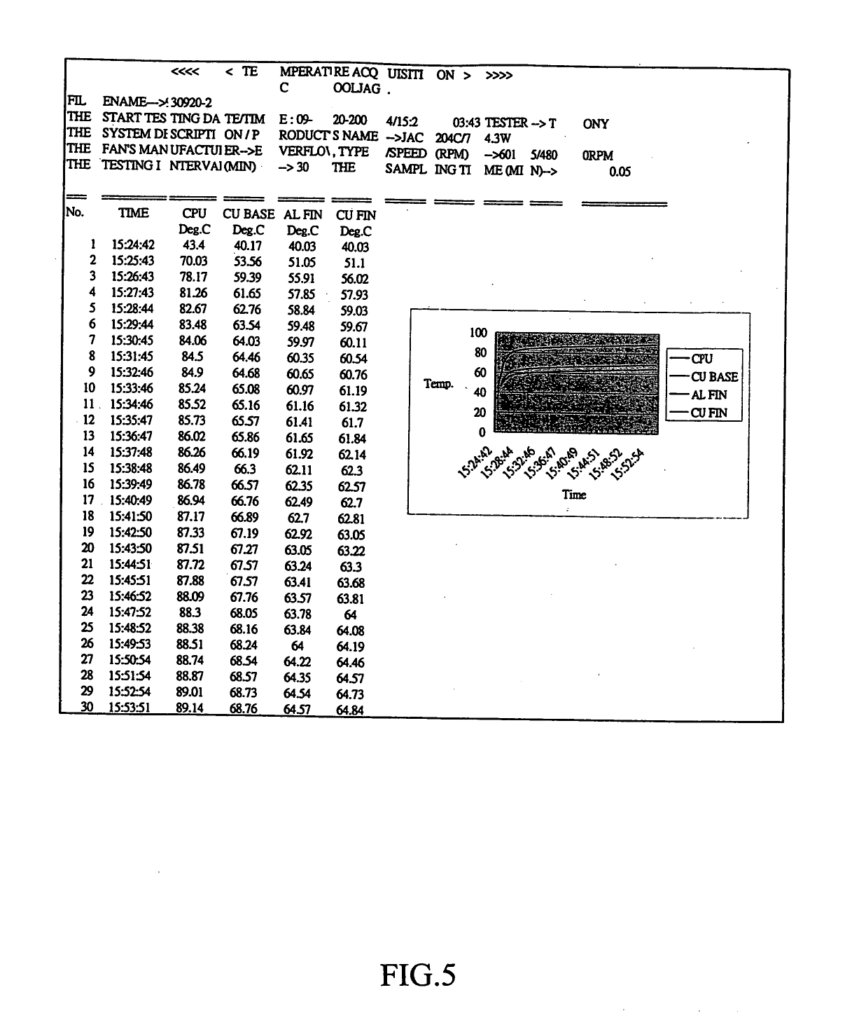

As shown FIG. 4 and FIG. 5 which shows the temperature in different spots of the heat dispensing device “A”. The spots that are checked are located at the base “B” and the conjunction portion between copper 1 and aluminum 2 of the fins. t1=68.76° C., t2=64.84° C., and t3=64.57° C. The spot of t1 is located close to the heat source so that t1 is the highest spot among the three spots and there is a decrease of 3.92° C. between the spots t1 and t2. The difference between the spots of t2 and t3 is 0.27° C., this means that the impedance is so small. It is proved that although the fins include two different metal materials, the heat can be efficiently transferred between the two metal materials. The heat dispensing device “A” improves the inherent shortcomings of the conventional heat dispensing device “A” which includes agent for connecting fins to the base “B” and the agent is an impedance for heat transferring.

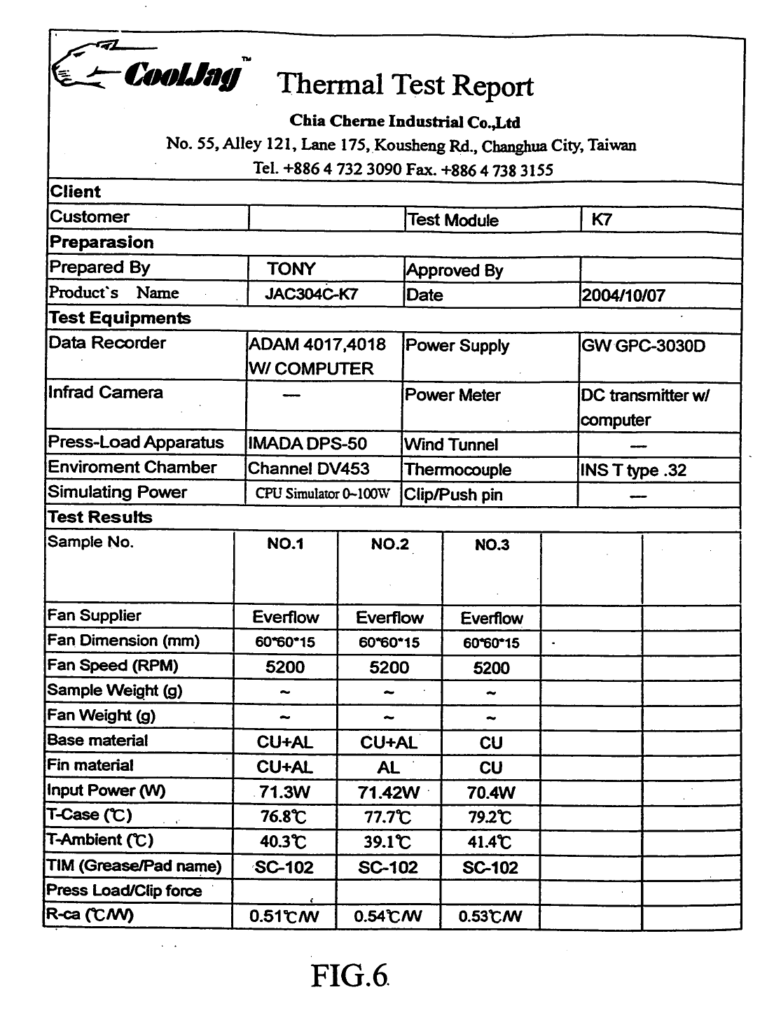

As shown in FIG. 6 which shows different spots of the heat dispensing device wherein No. 1 is the position where the tool for skving cuts at the copper and No. 1 is the position where the tool for skving cuts at the aluminum. The temperature of No. 1 is 0.15° C./W and 0.54° C./W for No. 2. If the tool for skving cuts at a part solely made by copper is 0.53° C./W. The result for No. 1 is close to No. 3 and superior to No. 2. This proves that the heat dispensing device is better than the conventional heat dispensing device and similar to a heat dispensing device solely made by copper.

While we have shown and described the embodiment in accordance with the present invention, it should be clear to those skilled in the art that further embodiments may be made without departing from the scope of the present invention.

What is claimed is:

1. A heat dispensing device comprising:
a base made of copper and a plurality of fins integrally extending from the base, the fins being made by aluminum.

2. The heat dispensing device as claimed in claim 1, wherein the fins are made by way of skving.

3. The heat dispensing device as claimed in claim 1, wherein no gap is defined between the base and the fins.

4. The heat dispensing device as claimed in claim 1, wherein the fins are made by compound material composed of copper and aluminum.
